(19) United States
(12) Patent Application Publication
(10) Pub. No.: US 2015/0305204 A1
(43) Pub. Date: Oct. 22, 2015

(54) DATA CENTER WITH COOLING SYSTEM

(71) Applicant: HON HAI PRECISION INDUSTRY CO., LTD., New Taipei (TW)

(72) Inventors: CHIH-HUNG CHANG, New Taipei (TW); SHIH-CHIEH CHEN, New Taipei (TW)

(73) Assignee: HON HAI PRECISION INDUSTRY CO., LTD., New Taipei (TW)

(21) Appl. No.: 14/256,389

(22) Filed: Apr. 18, 2014

(51) Int. Cl. H05K 7/20

(52) U.S. Cl. CPC H05K 7/20718

(57) ABSTRACT

Data center includes a first container, a second container, a first duct and a second duct. The first container includes an air intake for inputting outside cooling air, an air input window for inputting heated air, and an air exhaust. The outside cooling air and the heated air in the first container are mixed to be cooling air. The second container has data racks contained therein. The second container includes an air inlet and an air outlet. The first air duct couples the air exhaust of the first container and the air inlet of the second container, for guiding the cooling air from the first container to cool data equipment at the data racks. The second air duct couples the air outlet of the second container and the input window of the first container, for guiding the heated air from the second container to the first container.

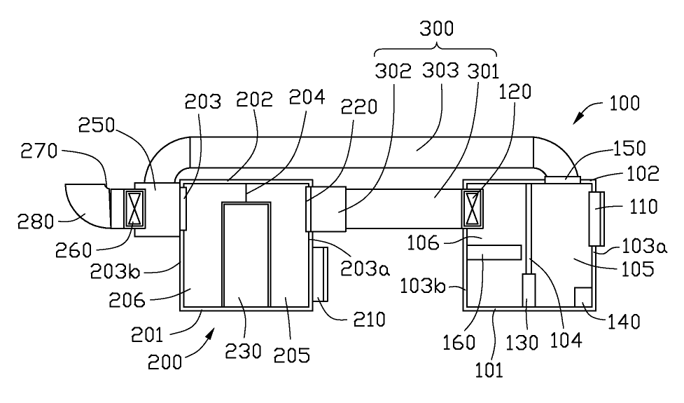

### FIELD

The present disclosure relates to data centers, and more particularly to a data center with cooling system.

### BACKGROUND

The advent of cloud computing and virtualization and other new technologies make data center evolved into a very different environment. A data center includes data center equipment such as servers, storage and networking equipment. Temperature and moisture are two important environment factors which impact operating performance of the data center equipment.

When the data center equipment works, they generate a lot of heat. The heat must be removed rapidly, otherwise, the heat accommodated in the data center produces high temperature of the data center equipment, which results in unstable working performance of the data center equipment. Typically, the data center applies a cooling system to introduce outside air to directly cool the data center equipment.

### BRIEF DESCRIPTION OF THE DRAWINGS

The FIGURE is a schematic side view of a data center with cooling system in accordance with an embodiment of the disclosure.

### DETAILED DESCRIPTION

In the following disclosure the term “couple” is defined as connect, whether directly or indirectly through intervening components, and is not necessarily limited to physical connections. The connection can be such that the objects are permanently connected or releasably connected.

Referring to the FIGURE, a data center in accordance with an exemplary embodiment is shown. The data center can be a container data center which is one type of the data center. The container data center includes a first container 100, a second container 200 and an air guiding system 300 coupling the first container 100 and the second container 200. In this embodiment, the first container 100 and the second container 200 can be horizontally and spaced positioned in a container.

The first container 100 can be a standard container. An insulation layer with a suitable thickness can be positioned on an inner face of the first container 100. The first container 100 includes a bottom 101, a ceiling 102 opposite to the bottom 101, a first sidewall 103a and a second sidewall 103b opposite to the first sidewall 103a. The first sidewall 103a and the second sidewall 103b both couple the bottom 101 and the ceiling 102. The first sidewall 103a defines a first air intake in an upper portion thereof. In this embodiment, a first air flow control device 110 can be arranged at the first air intake for inputting and controlling outside air into the first container 100. A dust filter can cover an air inlet of the first flow control device 110. The second sidewall 103b faces the second container 200 and defines an air exhaust in an upper portion thereof. An air driving device 120 can be arranged at the air exhaust, the air driving device 120 can include one or a plurality of fan(s)/blower(s).

In this embodiment, a first baffle plate 104 depends from the ceiling 102, a gap is left between the bottom 101 and the first baffle plate 104. The first baffle plate 104 can be made of heat insulating material. A first air mixing member 130 is received in the gap and located between the bottom 101 and the first baffle plate 104. The first air mixing member 130 can be vertically positioned. The first air mixing member 130 can include one or a plurality of porous plate(s). The porous plate can be a steel plate with a plurality of holes spaced from each other in a predetermined interval. The porous plate also can be a steel wire gauze. The first baffle plate 104 and the first air mixing member 130 cooperatively divide the first container 100 into a first room 105 and a second room 106. The first room 105 is located between the first baffle plate 104, the air mixing member 130 and the first sidewall 103a. The second room 106 is located between the first baffle plate 104, the first air mixing member 130 and the second sidewall 103b. A drain structure 140 is located in the first room 105 and at a joint of the first bottom 101 and the first sidewall 103a. The ceiling 102 defines an air input window 150 corresponding to the first room 105. The first room 105 communicates with the first air intake and the air input window 150. The second room 106 communicates with the air exhaust. A second air mixing member 160 is located in the second room 106, and extends from the second sidewall 103b towards the first baffle plate 104. The second air mixing member 160 is located below the air driving device 120. The second air mixing member 160 can be horizontally positioned. The second air mixing member 160 can include one or a plurality of porous plate(s). The porous plate can be a steel plate with a plurality of holes spacing from each other in certain interval. The porous plate also can be a steel wire gauze.

The second container 200 can be a standard container, and contains a plurality of data racks 230 therein. An insulation layer (not shown) with a suitable thickness can be positioned on an inner face of the second container 200. The second container 200 includes a bottom 201, a ceiling 202 opposite to the bottom 201, a first sidewall 203a and a second sidewall 203b opposite to the first sidewall 203a. The first sidewall 203a and the second sidewall 203b both couple the bottom 201 and the ceiling 202. The first sidewall 203a has an out surface facing the second sidewall 103b of the first container 100. The first sidewall 203a defines a second air intake (not labeled) in lower portion thereof. In this embodiment, a second air flow control device 210 can be arranged at the second air intake for inputting and controlling outside air into the second container 200. The second air flow control device 210 can be an electric air flow control device. A dust filter can cover an air intake of the second flow control device 210. The first sidewall 203a defines one or a plurality of air inlet(s) 220 in an upper portion thereof, for inputting air from the second room 106 of the first container 100. The second sidewall 203b faces outside and defines one or a plurality of air outlet(s) 240 in an upper portion thereof.

The second sidewall 203b can have a first air collecting case 250 arranged at and corresponding to the air outlet 240 of the second sidewall 203b. The first air collecting case 250 is attached with an exhaust air driving device 260 at a face thereof corresponding to the air outlet 240. The exhaust air driving device 260 can include one or a plurality of fan(s)/blower(s). A third air flow control device 270 can be arranged at an air outlet of the exhaust air driving device 260 for outputting and controlling volume of heated air from the second container 200 to ambient air. The third air flow control device 270 can further be attached with an exhaust air duct 280 at an air exhaust thereof. The exhaust air duct 280 has an air outlet thereof facing upwards, for keeping the heated air be dissipated upwards.

In the second container 200, a gap can be left between the ceiling 202 and a top of the data racks 230, a second baffle plate 204 is received in the gap. The second baffle plate 204 depends from the ceiling 202 towards the top of the data racks 230. The second baffle plate 204 can be made of heat insulating material. The second baffle plate 204 and the data racks 230 substantially divide the second container 200 into a cooling air channel 205 and a heated air channel 206. The cooling air channel 205 is located between the second baffle plate 204, the data racks 230 and the first sidewall 203a, and faces air inlets of data equipment such as network exchangers, servers and computers located at the data racks 230. The cooling air channel 205 communicates with the second air intake and the air inlet 220 of the first sidewall 203a. The heated air channel 206 is located between the second baffle plate 104, the data racks 230 and the second sidewall 203b. The heated air channel 206 communicates with the air outlet 240 of the second sidewall 203b.

The air guiding system 300 includes a first air duct 301 located between the first container 100 and the second container 200, and a second air duct 303 spanning over the first container 100 and the second container 200.

The first air duct 301 couples the air inlet 220 of the first sidewall 203a of the second container 200 with the air exhaust of the second sidewall 103b of the first container 100, for guiding air form the first container 100 to the second container 200. An insulation layer with a suitable thickness can be positioned on an out face and/or inner face of the first air duct 301. The air guiding system 300 can further include a second air collecting case 302 located between and coupling the air inlet 220 of the first sidewall 203a and the first air duct 301.

The second air duct 303 couples the air input window 150 of the ceiling 102 of the first container 100 and the first air collecting case 250 attached to the second sidewall 203b of the second container 200, for guiding air from the second container 200 to the first container 100. The second air duct 303 can be substantially inverted U-shaped. The second air duct 303 spans over most of the first container 100 and the entire container 200.

When the container data center works, the first air flow control device 110 on the first sidewall 103a inputs and controls outside cooling air into the first container 100. The second air duct 303 guides the heated air from the second container 200 into the first room 105 of the first container 100 via the air input window 150. The outside cooling air and the heated air meet in the first room 105, which can produce condensation in the first room 105, and the condensation are drained outwards by the drain structure 140. The outside cooling air and the heated air are mixed to be mixed cooling air by the first air mixing member 130 and are drawn into the second room 106 from the first room 105 of the first container 100. The mixed cooling air is further mixed by the second air mixing member 160 to be cooling air, and the cooling air is drawn by the air driving device 120 into the first air duct 301 and the first air collecting case 302. The cooling air in the first air collecting case 302 then enters the cooling air channel 205 via the air inlet 220 in the upper portion of the first sidewall 203a of the second container 200. The second air flow control device 210 on the lower portion of the first sidewall 203a inputs and controls outside cooling air into the second container 200. The cooling air from the first container 100 and the outside cooling air in the cooling air channel 205 blow to the data equipment at the data racks 230. The cooling air from the first container 100 and the outside cooling air input by the air flow control device 210 can be mixed before they blow to the data equipment at the data racks 230. When the cooling air passes the data equipment at the data racks 230, it removes heat generated by the data equipment and is heated to be the heated air in the heated air channel 206. The heated air in the heated air channel 206 is drawn into the second air collecting case 250, then one part of the heated air enters into the second air duct 303 to reach the first container 100, the other part of the heated air is exhausted into ambient air via the exhaust air driving device 260, the third air flow control device 270 and the exhaust air duct 280.

According to this embodiment, in the first container 100, the outside cooling air and the heated air from the second container 200 is mixed, by this manner, the moisture in the outside cooling air is reduced, which avoids oxidative damage or other adverse impact to the data equipment and the data racks 230. Additionally, the second container 200 further inputs outside cooling air in the cooling air channel 205 to cool the data equipment at the data racks 230, by this manner, a power usage effectiveness of the container data center is reduced.

Additionally, the outside cooling air can be natural air. When the outside cooling air is natural air, the data center introduces the natural air to reduce moisture of the natural air to directly cool the data equipment at the data racks 230, so the data center can be called as data center with free cooling system, and cooling cost for the data center is lowered, comparing with that for a traditional data center.

It is to be understood, however, that even though numerous characteristics and advantages of certain embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A data center, comprising:
a first container comprising an air intake for inputting outside cooling air, an air input window for inputting heated air, and an air exhaust, the cooling air and the heated air in the first container being mixed to be cooling air;
a second container having data racks for supporting data equipment, the second container comprising an air inlet and an air outlet;
a first air duct coupling the air exhaust of the first container and the air inlet of the second container, for guiding the cooling air from the first container into the second container to cool the data equipment in the second container; and
a second air duct coupling the air outlet of the second container and the input window of the first container, for guiding the heated air from the second container to the first container.

2. The data center of claim 1, wherein the first container comprises an air mixing device mixing the heated air and the outside cooling air in the first container to be the cooling air.

3. The data center of claim 2, wherein the first container further comprises a baffle plate, the baffle plate and the air mixing device dividing the first container into a first room and a second room.

4. The data center of claim 3, wherein the air inlet window and the air intake of the first container both are communicating with the first room, the air exhaust communicating with the second room.

5. The data center of claim 4, wherein the first container has an air flow control device located at the air intake for inputting and controlling the outside cooling air into the first room of the first container.

6. The data center of claim 4, wherein the first container further comprises a drain structure located in the first room.

7. The data center of claim 4, wherein the first container has an air driving device located at the air exhaust of the first container.

8. The data center of claim 1, wherein the second container defines another air intake for inputting outside cooling air together with the cooling air to cool the data equipment in the second container.

9. The data center of claim 8, wherein the second container has an air flow control device located at the another air intake of the second container.

10. The data center of claim 8, wherein the second container further comprises a baffle plate, the baffle plate and data racks cooperatively dividing the second container to a cooling air channel adjacent tothe data racks and communicating with the air inlet and the another air intake of the second container, and a heated air channel communicating with the air outlet of the second container.

11. The data center of claim 1, wherein the second container has an air collecting case located at the air outlet for collecting the heated air from the second container, the second air duct coupling the second container via the air collecting case.

12. The data center of claim 11, wherein the air collecting case has an air driving device attached thereto, the air driving device facing the air outlet of the second container.

13. The data center of claim 1, wherein the first container and the second container are spaced apart from each other.

14. A data center, comprising:
a first container, a second container containing data racks for supporting data equipment, a first air duct coupling the first container and the second container for guiding cooling air from the first container to cool the data equipment in the second container, and a second air duct coupling the first container and the second container for guiding heated air from the second container to the first container.

15. The data center of claim 14, wherein the first air duct locates between the first container and the second container.

16. The data center of claim 15, wherein the second air duct spans over the second container.

17. The data center of claim 16, wherein the second air duct communicates with the second container via an air collecting case located at the air outlet of the second container.

18. The data center of claim 16, wherein the first container defines an air intake for inputting outside cooling air into the first container, the first container comprising a first room communicating with the air intake and a second room separated from the first room, the second container comprising a cooling air channel and a heated air channel, the data racks facing the cooling air channel, the first air duct coupling the second room and the cooling air channel, the second air duct coupling the first room and the heated air channel.

19. The data center of claim 18, wherein the first container comprises a drain structure in the first room of the first container.

20. The data center of claim 14, wherein the first container contains an air mixing member for mixing the heated air and outside cooling air input by the first container to be the cooling air which is guided into the second container by the first air duct.
